(19) United States
(12) Patent Application Publication
(10) Pub. No.: US 2006/0244056 A1
(43) Pub. Date: Nov. 2, 2006

(54) Semiconductor device

(75) Inventor: Yoshinao Miura, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/412,045

(22) Filed: Apr. 27, 2006

(30) Foreign Application Priority Data
Apr. 28, 2005 (JP) 2005-130810
Apr. 6, 2006 (JP) 2006-105427

(51) Int. Cl. H01L 29/94

(52) U.S. Cl. 257/330

(57) ABSTRACT

A semiconductor device having a vertical MOSFET structure well balanced between high withstand voltage and low ON resistance is provided as having an n⁺-type semiconductor substrate 101 as a first-conductivity-type semiconductor substrate, an n-type drift region 102 as a first-conductivity-type drift region formed on the surface of an n⁺-type semiconductor substrate 101, a p-type base region 108 as a second-conductivity-type base region formed in the surficial portion of the n-type drift region 102, a p-type buried region 4 as a second-conductivity-type buried region provided in the n-type drift region 102, as being spaced from the p-type base region 108 towards the n⁺-type semiconductor substrate 101, and a gate electrode 107A provided so as to penetrate the p-type base region 108 and further to reach a predetermined depth in the n-type drift region 102.

This application is based on Japanese patent application Nos. 2005-130810 and 2006-105427 the contents of which are incorporated hereinto by reference.

### DISCLOSURE OF THE INVENTION

1. Field of the Invention

The present invention relates to a semiconductor device, and in particular to a semiconductor device having a high-voltage MOSFET structure.

2. Related Art

In general, semiconductor devices can roughly be classified into those of lateral type having electrodes on one side thereof, and those of vertical type having electrodes on both sides thereof. In particular, the vertical semiconductor devices can more readily reduce the cell size and to further increase the ON current, because they adopt a trench gate structure in which the cannel is formed normal to a wafer, unlike the lateral type ones having the channel formed in the surficial portion of the wafer. In thus-configured vertical semiconductor devices, both of direction of flow of drift current during the ON time, and direction of extension of a depletion layer contributed by reverse bias voltage during the OFF time are aligned to the thickness-wise (vertical) direction of the substrate. In view of raising the withstand voltage of the vertical semiconductor devices in which current flows between the electrodes respectively provided on two opposing main surfaces, it was necessary to increase specific resistivity and thickness of a high-resistivity layer between the electrodes. This consequently makes a semiconductor device of a larger withstand voltage more likely to increase the ON resistance.

On the other hand, in view of realizing low ON resistance, it is necessary to increase impurity concentration of the drift region through which the drift current flows, or to reduce thickness of the drift region. This, however, results in decrease in the thickness of the depletion layer produced during the OFF time, and consequently degrades the withstand voltage.

As described in the above, the withstand voltage and the ON current are in a trade-off relation. In view of downsizing low-power-consumption devices, it is necessary to reduce the ON resistance while keeping high withstand voltage of the device unchanged.

Japanese laid-Open Patent Publication No. 2002-222949 (FIG. 5, for example) and Japanese Laid-Open Patent Publication No. 9-191109 (FIG. 45, for example) disclose semiconductor devices each having a vertical super-junction MOSFET structure, in which a p-type buried region is provided in the middle of the n-type drift region so as to achieve high withstand voltage and low ON resistance.

### SUMMARY OF THE INVENTION

The present inventors made extensive investigations into conditions realizing high withstand voltage and low ON resistance of the semiconductor devices having the vertical super-junction MOSFET structure, and found out that the number of locations where the electric field would concentrate can be minimized and thereby the semiconductor devices can be improved in the withstand voltage and lowered in the ON resistance, by making the depth profile of electric field in the drift layer upon being applied with the breakdown voltage uniform, and the findings lead us to the present invention.

According to the present invention, there is provided a semiconductor device having a MOSFET structure, which includes:

a first-conductivity-type semiconductor substrate,

a first-conductivity-type drift region formed on the surface of the first-conductivity-type semiconductor substrate,

a second-conductivity-type base region formed in the surficial portion of the first-conductivity-type drift region,

a second-conductivity-type buried region provided in the first-conductivity-type drift region as being spaced from the second-conductivity-type base region towards the substrate, and

a gate electrode provided so as to penetrate the second-conductivity-type base region and further to reach a predetermined depth in the first-conductivity-type drift region,

wherein the end portion of the second-conductivity-type buried region on the second-conductivity-type base region side is located, in the thickness-wise direction of the first-conductivity-type drift region, at an almost same level with the end portion of the gate electrode in the first-conductivity-type drift region.

In the above-described semiconductor device, it is also allowable that the second-conductivity-type buried region comprises at least two regions disposed as being spaced from each other in the thickness-wise direction of the first-conductivity-type drift region, and that the end portion on the second-conductivity-type base region side of one region, closest of these regions to the second-conductivity-type base region, is located at an almost same level with the level of the end portion of the gate electrode in the first-conductivity-type drift region, in the thickness-wise direction of the first-conductivity-type drift region.

It is also allowable in the semiconductor device that the second-conductivity-type buried region is formed in a region of the first-conductivity-type drift region, which falls between a plurality of the gate electrodes in a plan view.

The semiconductor device of the present invention does not cause current flow between the drain electrode and the source electrode, that is, the device is turned off, under no applied voltage between the gate electrode and the source electrode, and under reverse voltage applied between the drain electrode and the source electrode, because a depletion layer extends from each of two junctions, one of which resides between the first-conductivity-type drift region and the second-conductivity-type base region, and the other resides between the first-conductivity-type drift region and the second-conductivity-type buried region.

On the other hand, the semiconductor device under a bias voltage applied between the gate electrode and the source electrode produces an inverted state in the surficial portion of the second-conductivity-type base region opposed to the gate electrode, so as to form a channel, allowing current to flow therethrough corresponding to the voltage between the drain electrode and the source electrode, which means the ON state.

The semiconductor device can realize high withstand voltage, because the second-conductivity-type buried region and the second-conductivity-type base region, both of which being formed in the first-conductivity-type drift region, are not brought into contact with each other, and instead, the first-conductivity-type drift region of a sufficient thickness is placed between these regions. On the other hand, the end portion of the second-conductivity-type buried region on the second-conductivity-type base region side is located at the same level with the end portion of the gate electrode in the first-conductivity-type drift region, in the thickness-wise direction of the first-conductivity-type drift region, so that the depth profile of electric field in the drift layer upon being applied with the breakdown voltage is made uniform, the number of locations where the electric field would concentrate can be reduced, and thereby it is made possible to further improve the withstand voltage even if the ON resistance remains unchanged. As is clear from the above, the balance between high withstand voltage and low ON resistance can be optimized. It is therefore made possible to maximize the breakdown voltage while minimizing the ON resistance.

According to the present invention, it is made possible to provide a semiconductor device having a vertical MOSFET structure well balanced between high withstand voltage and low ON resistance.

### BRIEF DESCRIPTION OF THE DRAWINGS

The above and other objects, advantages and features of the present invention will be more apparent from the following description taken in conjunction with the accompanying drawings, in which:

FIG. 1 is a sectional view showing a semiconductor device of one embodiment;

FIG. 2 is a sectional view showing a conventional semiconductor device;

FIG. 3 is a drawing schematically showing a potential contour plane of the semiconductor device shown in FIG. 1, upon being applied with the breakdown voltage;

FIGS. 4A and 4B are drawings schematically showing potential contour planes of semiconductor devices both of which having the different structure shown in FIG. 3, upon being applied with the breakdown voltage;

FIGS. 5 to 8 are sectional views showing process steps of fabricating the semiconductor device of the above-described embodiment; and

FIG. 9 is a sectional view showing a semiconductor device of another embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Paragraphs below will detail an embodiment of the semiconductor device according to the present invention, referring to the attached drawings.

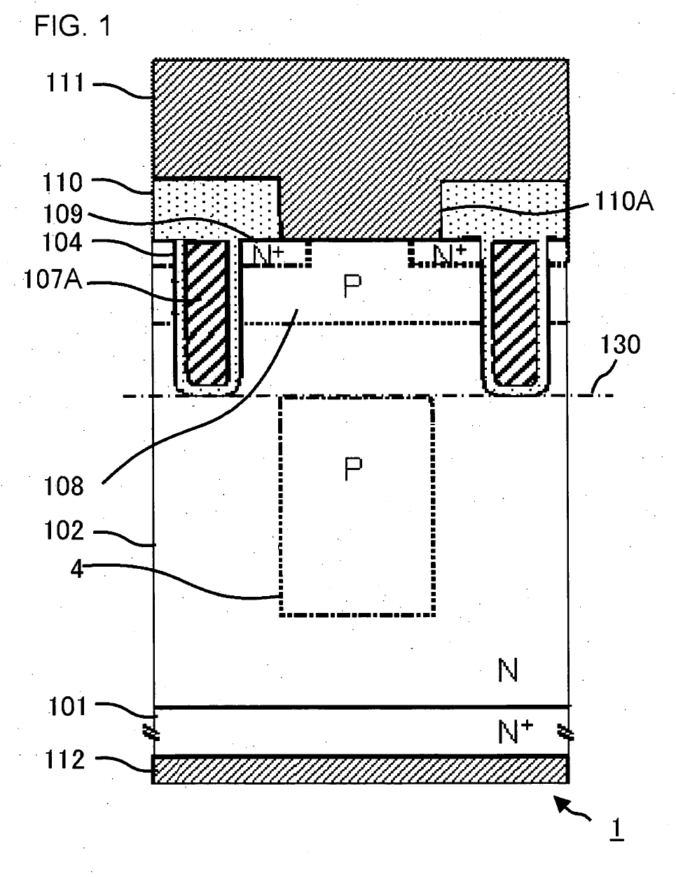

It is to be noted that any components commonly appear in the drawings will be given with same reference numerals, so as to allow omission of repetitive explanations. FIG. 1 is a sectional view showing a semiconductor device of this embodiment.

A semiconductor device 1 has a MOSFET structure, and includes an n⁺-type semiconductor substrate 101 as the first-conductivity-type semiconductor substrate, an n-type drift region 102 as the first-conductivity-type drift region formed on the surface of the n⁺-type semiconductor substrate 101, a p-type base region 108 as the second-conductivity-type base region formed in the surficial portion of the n-type drift region 102, a p-type buried region 4 as the second-conductivity-type buried region provided in the n-type drift region 102 as being spaced from the p-type base region 108 towards the n⁺-type semiconductor substrate 101, and a gate electrode 107A provided so as to penetrate the p-type base region 108 and further to reach a predetermined depth in the n-type drift region 102.

For the case where the semiconductor device 1 is configured by a plurality of MOSFET elements two-dimensionally arranged one after another while configuring each of the gate electrodes 107A as having a trench geometry, it is allowable to form the p-type buried region 4 in a region of the n-type drift region 102 which falls between such plurality of gate electrodes 107A in a plan view.

In the semiconductor device 1, the n⁺-type semiconductor substrate 101 is composed of a heavily doped n-type semiconductor, has the n-type drift region 102 on one surface thereof, and has a drain electrode 112 composed of a metal electrode formed on the other surface thereof.

The n-type drift region 102 is composed of an epitaxial layer formed typically by epitaxial growth of silicon, while being doped with silicon, on the surface of the n⁺-type semiconductor substrate 101. In the surficial portion of the n-type drift region 102, there is formed the p-type base region 108.

In the n-type drift region 102, there is provided a p-type buried region 4. The p-type buried region 4 is provided at a predetermined depth in the thickness-wise direction of the n-type drift region 102, so that the end portion thereof on the p-type base region 108 side is located at the same level with the end portion of the gate electrode 107A in the n-type drift region 102, in the thickness-wise direction of the n-type drift region 102, in other words, so that the end portions of both regions are aligned at the level of a line 130.

The gate electrode 107A is formed so as to penetrate the p-type base region 108 and so as to be partially buried in the in the n-type drift region 102, to thereby allow itself to oppose with the n-type drift region 102, the p-type base region 108 and the later-described n⁺-type source region 109, while placing a gate oxide film 104 in between. When a plurality of MOSFET devices are continuously provided in a planer manner, the gate electrodes 107A are generally connected to each other in a reticular pattern or a meshed pattern (not shown). A region laid out by the reticular pattern or meshed pattern constitutes one MOSFET device.

On the top surface side of the p-type base region 108, there is provided the n⁺-type source region 109 as the first-conductivity-type source region so as to locate between each gate electrode 107A. In the other words, the n⁺-type source region 109 formed at right side of the left gate electrode 107A in FIG. 1 and that formed at left side of the right gate electrode 107A in FIG. 1 are connected to each other both at upper and lower sides of the drawings to form a ring (not shown). The n⁺-type source region 109 and the p-type base region 108 are connected to a source electrode 111 through a contact hole 110A. The source electrode 111 and the gate electrode 107A are opposed with each other while placing an interlayer insulating film 110 in between, and are not electrically connected.

In thus-configured semiconductor device, under no applied voltage between the gate electrode 107A and the source electrode 111, and under reverse voltage applied between the drain electrode 112 and the source electrode 111, a depletion layer extends from each of two junctions, one of which resides between the n-type drift region 102 and the p-type base region 108, and the other resides between the n-type drift region 102 and the p-type buried region 4, so that current does not flow between the drain electrode 112 and the source electrode 111, which means OFF state.

On the other hand, the semiconductor device shown in FIG. 1 under a bias voltage applied between the gate electrode 107A and the source electrode 111 produces an inverted state in the surficial portion of the p-type base region 108 opposed to the gate electrode 107A, so as to form a channel, allowing current to flow therethrough corresponding to the voltage between the drain electrode 112 and the source electrode 111, which means the ON state.

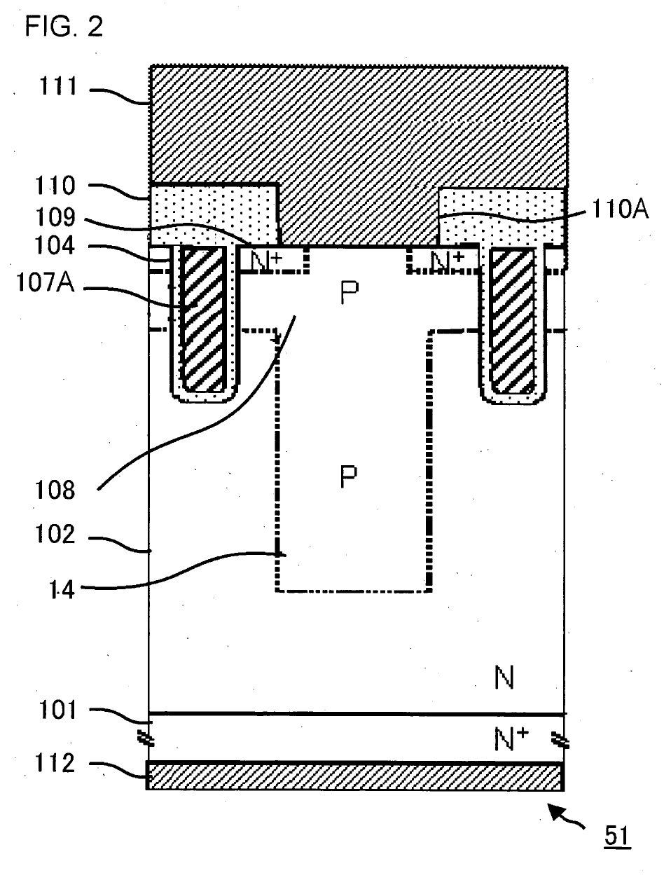

Application of drain bias in the OFF state induces the depletion layer which extends from the junction plane between the n-type drift region 102 and the p-type buried region 4. Maximum withstand voltage can be obtained when the p-type buried region 4 is completely depleted, and at the same time the n-type drift region 102 is depleted to a depth almost equivalent to that of the p-type buried region 4, and such state is realized when the number of ionized donors and the number of ionized acceptors almost coincide with each other (charge balance). A previously existing super-junction power MOSFET having the trench gates as shown in FIG. 2 has a p-type column region 14 formed so as to contact with the bottom of the p-type base region 108, and has no n-type region in this region, so that region in the vicinity of the bottom of the p-type base region 108 becomes acceptor-excessive. In contrast to this, the semiconductor device of this embodiment has an n-type drift region 102 as the n-type region having a sufficient thickness between the p-type buried region 4 and the p-type base region 108, and this consequently raises the impurity concentration of the n-type drift region 102, to thereby realize the charge balance as described in the above.

This embodiment therefore makes it possible to obtain a predetermined withstand voltage, and at the same time to realize low ON resistance, even under a raised impurity concentration of the n-type drift region 102, in a more successful manner over the previously existing semiconductor device 51 as shown in FIG. 2, having the vertical super-junction MOSFET structure in which the p-type column region 14 is formed in the n-type drift region 102 so as to contact with the p-type base region 108, rather than forming the p-type buried region as described in this embodiment.

On the other hand, the semiconductor device 1 can no more sustain the OFF state, if voltage applied to the drain electrode 112 is gradually increased in the OFF state, and absolute value of the electric field exceeds the critical voltage elsewhere in the semiconductor device 1, due to a large avalanche current produced therein. This state is known as the breakdown state, and a minimum drain voltage inducing the avalanche current refers to the breakdown voltage, which means withstand voltage of the semiconductor device.

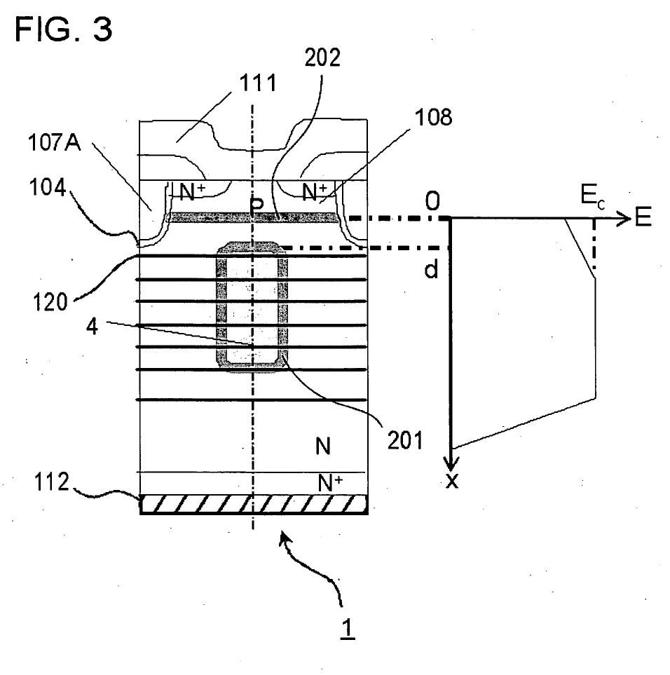

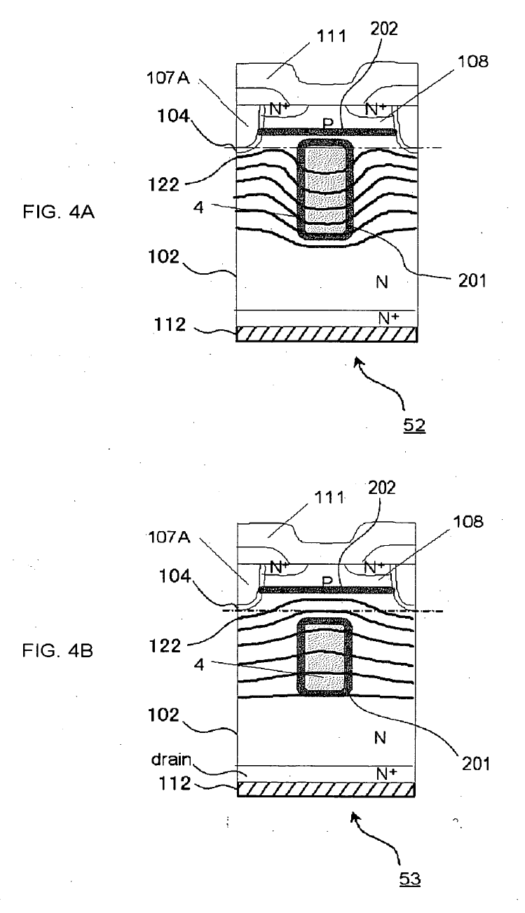

FIG. 3 is a drawing schematically showing a depth profile of the electric field, or a potential contour plane, of the semiconductor device of this embodiment shown in FIG. 1, upon being applied with the breakdown voltage. FIGS. 4A and 4B are drawings schematically showing potential contour planes of semiconductor devices both of which having the different structure shown in FIG. 3, upon being applied with the breakdown voltage.

The semiconductor device 1 shown in FIG. 3 is configured so that the top surface, or the surface on the p-type base region 108 side, of the p-type buried region 4, and the bottom surface, or the surface on the n-type drift region 102 side, of the gate electrode 107A are located at an almost same level.

It is to be understood that “almost same level” herein means that the upper end of the depletion layer 201 having a width of (w/2), extending as being centered round and over the top surface of the p-type buried region 4 under no applied voltage between the source and drain regions, resides at a level higher than the lower end of the gate oxide film 104 in the n-type drift region 102, or the trench gate bottom, and that the lower end of the depletion layer 201 having a width of (w/2), extending as being centered round and under the top surface of the p-type buried region 4 resides at a level lower than the lower end of the gate electrode 107A.

As shown in FIG. 3, there is also generated a depletion layer 202 under the zero-bias application in the surface portion of the p-type base region 108 on the p-type buried region 4 side. Here, the width w of the depletion layer 201 generated in the surface portion of the p-type buried region 4 is taken as an index of spreading of the depletion layer. The width w of the depletion layer 201 is defined as a sum of the width of the depletion layer extending as being centered round the top surface of the p-type buried region 4 into the n-type drift region 102 and the width of the depletion layer extending into the p-type buried region.

Now the width w of the depletion layer 201 generated under the zero-bias application is defined as below: [Mathematical formula 1]

$$w = \sqrt{\frac{2 ɛ \times Vb}{q \times N}} \qquad [ Mathematical formula 1 ]$$

where, c represents dielectric constant of the n⁺-type semiconductor substrate 101. Vb represents built-in potential, which is difference in energy levels between n-type semiconductor and p-type semiconductor bands. q represents amount of charge, which is a constant. N represents impurity concentration in the n-type drift region 102.

According to the configuration as described in the above, potential curves representing potential contour planes in the n-type drift region 102 upon being applied with the breakdown voltage are made uniform between the source electrode 111 and the drain electrode 112, and the electric field distribution in the n-type drift region 102 in the thickness-wise direction thereof is made uniform at the critical voltage Ec. As a consequence, the number of locations where the electric field would concentrate can be reduced both in the n-type drift region 102 and in the p-type buried region 4, and this makes it possible to further improve the withstand voltage.

FIG. 4A shows a structure of a semiconductor device 52 in which the depletion layer 201 of width w, extending along the top surface of the p-type buried region 4, resides at a level higher than the trench gate bottom, or the lower end of the gate electrode 107A. Electric field distribution under voltage application between the source electrode 111 and the drain electrode 112 gives a particularly large value right under the trench gate bottom. This corresponds to an excessive amount of an acceptor impurity in the p-type buried region 4 in the vicinity of the base 108 (deviation from charge balance), so that the electric field in the n-type drift region 102 right under the trench gate bottom reaches earlier to the critical electric field Ec, and thereby the withstand voltage is lowered than in the case shown in FIG. 3.

FIG. 4B shows a structure of a semiconductor device 53 in which the depletion layer 201 of width w, extending along the top surface of the p-type buried region 4, resides at a level lower than the lower end of the gate oxide film 104 at the trench gate bottom. Electric field distribution under voltage application between the source electrode 111 and the drain electrode 112 gives a particularly large value right under the base 108. This corresponds to an excessive amount of a donor impurity in a region of the n-type drift region 102 which falls between the p-type buried region 4 and the base 108 (deviation from charge balance), so that the electric field in the region right under the base 108 reaches earlier to the critical electric field Ec, and thereby the withstand voltage is lowered than in the case shown in FIG. 3.

As described in the above, the withstand voltage of the semiconductor devices having the depletion layer 201 of width w, extending along the top surface of the p-type buried region 4, at a level higher (FIG. 4A) or lower than the lower end of the gate oxide film 104 (FIG. 4B) than the trench gate bottom, or the lower end of the gate electrode 107A, becomes smaller than that of the semiconductor device having the upper end of the depletion layer 201 at a level higher than the lower end of the gate oxide film 104, and having the lower end of the depletion layer 201 at a level lower than the lower end of the gate electrode 107A (FIG. 3). In other words, a sufficient level of withstand voltage can be obtained, if the p-type buried region 4 is formed at a position allowing at least a portion of the width, out of the entire width w, of the depletion layer 201 extending along the top surface of the p-type buried region to overlap the gate oxide film 104 at the trench gate bottom. Taking variations in the product into account, it is preferable in view of more stably obtaining a necessary level of withstand voltage, to design the p-type buried layer 4 so that the position of the upper end thereof falls within a range from the lower end to the upper end of the gate oxide film 104. On the other hand, the ON resistance does not largely vary even if the level of the top surface of the p-type buried region 4 varies. As is clear from the above, the semiconductor device of this embodiment makes it possible to optimize the balance between high withstand voltage and low ON resistance.

It is to be noted that both of Japanese Laid-Open Patent Publication Nos. 2002-222949 and 9-191109 disclose techniques of forming a region corresponded to the p-type buried region 4 of this embodiment in a region corresponded to the n-type drift region 102 of this embodiment, so as to be spaced from the p-type base region, to thereby achieve high withstand voltage and low ON resistance. Both of which correspond to the case shown in FIG. 4B. The semiconductor device according to the present invention is therefore superior to the semiconductor devices disclosed in Japanese Laid-Open Patent Publication Nos. 2002-222949 and 9-191109 in terms of the balance between high withstand voltage and low ON resistance.

The semiconductor device shown in FIG. 1 can be fabricated typically by the procedures below.

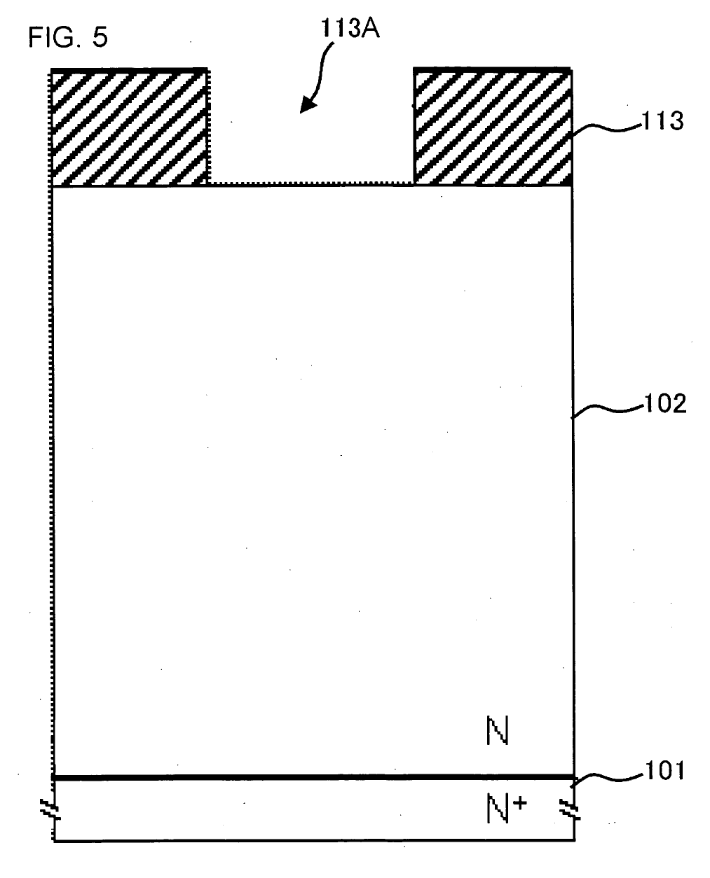

As shown in FIG. 5, the n⁺-type semiconductor substrate 101 which is a heavily-doped silicon substrate is prepared, and the n-type drift region 102 is formed on thus obtained n⁺-type semiconductor substrate 101, typically by allowing silicon to epitaxially grow thereon while being doped with phosphorus. The impurity concentration herein is adjusted so as to be lowered in the n-type drift region 102 than in the n⁺-type semiconductor substrate 101. Next, an oxide film 113 is formed on the surface of the n-type drift region 102 typically by the CVD process, and the oxide film 113 is then selectively etched, with the aid of a photolithographic technique, to thereby form an opening 113A in the oxide film 113. The geometry of the opening 113A herein may be any of square, rectangle, those having transformed corner portions, and stripe sufficiently elongated in one of the edges.

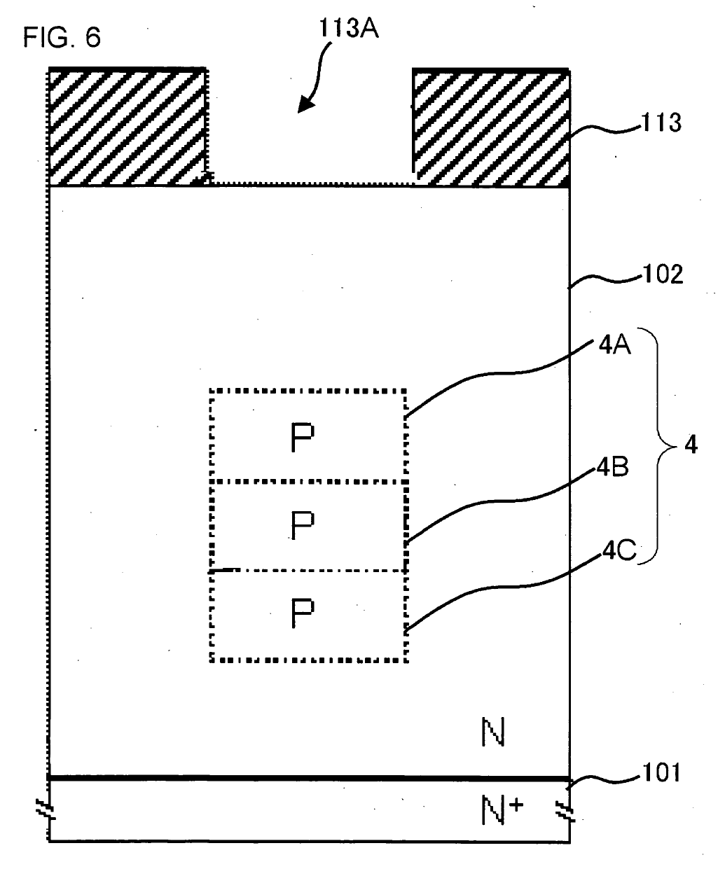

Next, as shown in FIG. 6, boron ions are implanted into the n-type drift region 102 through the opening 113A, to thereby form the p-type buried region 4 in a region below the opening 113A. The boron ion implantation is carried out as being divided into a plural number of times, under varied energy of implantation. More specifically, boron ions are implanted at a predetermined energy C to thereby form a p-type buried region 4C, boron ions are again implanted at another predetermined energy B smaller than energy C to thereby form a p-type buried region 4B, and boron ions are still again implanted at another predetermined energy A smaller than energy B to thereby form a p-type buried region 4A. The boron ions are then diffused and activated typically by annealing at 900° C. so as to make the p-type buried regions 4A to 4C continuous, to thereby form the p-type buried region 4. In the ion implantation, ions are desirably scattered on the inner wall of the opening 113A, so that the p-type buried region 4 will have a cylindrical geometry having an almost smooth side face.

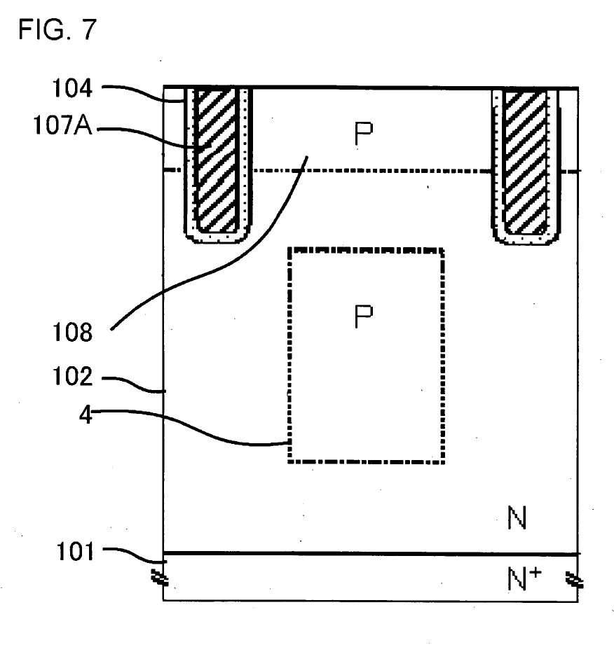

Next as shown in FIG. 7, the n-type drift region 102 is selectively etched, with the aid of a photolithographic technique, to thereby form a trench, and the gate oxide film 104 is formed on the inner wall of the trench by a thermal oxidation technique. Next, polysilicon is deposited typically by the CVD process over the entire surface, and is then etched back so as to leave it selectively in the trench, to thereby form the gate electrode 107A in the trench. In this process, the trench is formed to a depth same as the level of the top surface of the p-type buried region 4, so as to consequently adjust the level of the bottom surface of the gate electrode 107A to the level of the top surface of the p-type buried region 4, in the thickness-wise direction of the n-type drift region 102. In an exemplary case, the gate oxide film 104 is formed to as thick as 50 nm or around, whereas the depletion layer has a width w of 0.3 to 0.4 μm or around. A process design allowing the position of the trench bottom to fall on the position of the top surface of the p-type buried region 4 makes it possible to fabricate the semiconductor device of the present invention with a sufficient stability despite possible variations in the production.

Next, boron ions are implanted using the gate electrode 107A as a mask, and then annealed, to thereby form the p-type base region 108 in the surficial portion of the n-type drift region 102 in a self-aligned manner. In this embodiment, the p-type buried region 4 can be formed as being spaced from the p-type base region 108, by adjusting the minimum ion implantation energy for forming the p-type buried region 4 sufficiently larger than the ion implantation energy for forming the p-type base region 108. The boundary between the p-type base region 108 and the n-type drift region 102 is made almost flat.

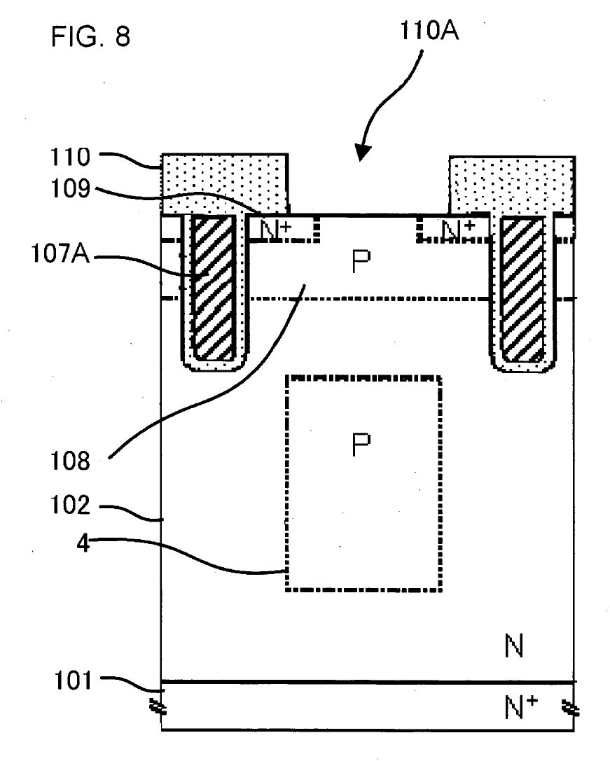

Next as shown in FIG. 8, arsenic (As) is selectively implanted into the p-type base region 108, with the aid of a photolithographic technique, and is then annealed, so as to invert the conductivity type of a region in the surficial portion of the p-type base region 108 and around the gate electrode 107A into high concentration n-type (n⁺), to thereby form the n⁺-type source region 109. Next, the interlayer insulating film 110 is formed typically by depositing BPSG (boro-phospho silicated glass) by the CVD process, and is then selectively etched, with the aid of a photolithographic technique, to thereby form a contact hole 110A in a region covering the p-type base region 108 and the n⁺-type source region 109.

Further thereon, an aluminum film is deposited by the sputtering process over the entire surface including inside of the contact hole 110A to thereby form the source electrode 111 as shown in FIG. 1, and the drain electrode 112 is formed on the back surface of the n⁺-type semiconductor substrate 101. The semiconductor device 1 is thus obtained.

The p-type buried regions 4A to 4C in the above-descried embodiment were formed in a geometrically continuous manner as shown in FIG. 6, whereas it is also allowable to adjust the ion implantation energy so as not to form the portion corresponded to the p-type buried region 4B, to thereby provide the p-type buried regions 4A and 4C as being spaced from each other.

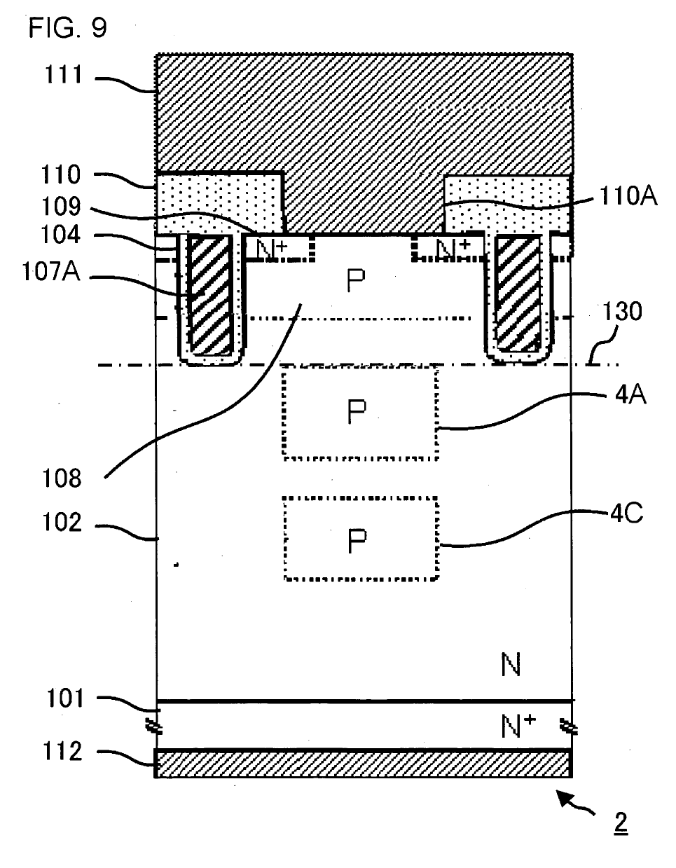

More specifically, the p-type buried region as the second-conductivity-type buried region may be composed of at least two regions 4A, 4C as shown in FIG. 9, and these regions may be provided as being spaced from each other in the depth-wise direction of the n-type drift region 102. The semiconductor device 2 in this case can be configured so that the end portion on the p-type base region 108 side of the p-type buried region 4A, which is the closest of these p-type buried regions 4A, 4C to the p-type base region 108, is located at the same level with the level of the end portion of the gate oxide film 104 in the n-type drift region 102, in the thickness-wise direction of the n-type drift region 102, in other words, so that the end portions of both regions are aligned at the level of the line 130. It is to be noted herein that, as explained previously, it is all enough that a range of the width w of the depletion layer extending along the top surface of the p-type buried region 4A overlaps a range of the thickness of the gate oxide film 104 at the trench bottom, wherein even the case in which the end portions of both regions are not aligned at the position of the line 130 can yield the effects of the present invention.

As is clear from the above, this embodiment makes it possible to provide a semiconductor device having a vertical MOSFET structure, well balanced between high withstand voltage and low ON resistance.

The embodiment in the above dealt with the semiconductor device using a heavily-doped, n-type semiconductor substrate, in which the region composed of a p-type semiconductor layer is formed in the drift region composed of an n-type semiconductor layer, whereas it is of course obvious that also a semiconductor device having the n-type and p-type semiconductor layers exchanged therein can give effects similar to those in the above embodiment.

Paragraphs below will explain the semiconductor device of the present invention referring to Examples, without limiting the present invention.

### EXAMPLE 1

The semiconductor device 2 shown in FIG. 9 was fabricated under the conditions listed in Table 1.

More specifically, on a silicon wafer (n⁺-type semiconductor substrate 101) having the donor concentration Nd of the n-type drift region 102 adjusted to 5E16 (cm⁻³), a power MOSFET having a design pitch of trench of 3 μm was fabricated. The opening 113A through which the p-type buried regions 4A, 4C are formed later was formed as a slit having a width of 1.6 μm, so that the p-type buried region 4A, 4C formed by high-energy ion implantation had a stripe pattern. The ion implantation was carried out twice under the conditions listed in Table 1, and other conditions were optimized so as to obtain a maximum withstand voltage.

Thus obtained power MOSFET was found to have a withstand voltage of 59.5 V, and an ON resistance of 16.5 mΩmm².

### EXAMPLE 2

The semiconductor device 1 shown in FIG. 1 was fabricated under the conditions listed in Table 1.

More specifically, the power MOSFET was fabricated similarly to as described in Example 1, except that the high-energy ion implantation was carried out three times under the conditions listed in Table 1.

Thus obtained power MOSFET was found to have a withstand voltage of 63.0 V, and an ON resistance of 16.7 mΩmm².

### COMPARATIVE EXAMPLE

The semiconductor device 51 shown in FIG. 2 was fabricated under the conditions listed in Table 1.

More specifically, the power MOSFET was fabricated similarly to as described in Example 1, except that the high-energy ion implantation was carried out four times under the conditions listed in Table 1, so as to form the p-type buried region as the column region 14 in contact with the p-type base region 108, rather than forming it as being spaced from the p-type base region 108 as described in Examples 1, 2.

Thus obtained power MOSFET was found to have a withstand voltage of 47.4 V, and an ON resistance of 17.0 mΩmm².

TABLE 1

| | NUMBER OF TIMES OF | DOSE(cm⁻²) | | | | WITHSTAND | ON |
|---|---|---|---|---|---|---|---|
| | ION IMPLANTATION | 1.5 MeV | 1.0 MeV | 0.5 MeV | 0.2 MeV | VOLTAGE | RESISTANCE |
| SEMICONDUCTOR DEVICE 2 | 2 | 5.5E+12 | — | 5.5E+12 | — | 59.5 V | 16.5 mΩmm² |
| SEMICONDUCTOR DEVICE 1 | 3 | 3.0E+12 | 3.0E+12 | 3.0E+12 | — | 63.0 V | 16.7 mΩmm² |
| SEMICONDUCTOR DEVICE 51 | 4 | 2.5E+12 | 2.5E+12 | 2.5E+12 | 2.5E+12 | 47.4 V | 17.0 mΩmm² |

As described in the above, it was found from comparison between the conventional semiconductor device 51 having a conventional vertical-MOSFET structure fabricated in Comparative Example and the inventive semiconductor devices fabricated in Examples 1, 2 that the semiconductor devices 2, 1 in Examples 1, 2 can realize higher withstand voltage while suppressing the ON resistance at equivalent levels. In other words, it was suggested that the semiconductor device of the present invention can realize lower ON resistance even if the withstand voltage remains at the same level with that of the conventional one.

It is apparent that the present invention is not limited to the above embodiments, that may be modified and changed without departing from the scope and spirit of the invention.

What is claimed is:

1. A semiconductor device having a MOSFET structure, comprising:
a first-conductivity-type semiconductor substrate,
a first-conductivity-type drift region formed on the surface of said first-conductivity-type semiconductor substrate,
a second-conductivity-type base region formed in the surficial portion of said first-conductivity-type drift region,
a second-conductivity-type buried region provided in said first-conductivity-type drift region as being spaced from said second-conductivity-type base region towards said substrate, and
a gate electrode provided so as to penetrate said second-conductivity-type base region and further to reach a predetermined depth in said first-conductivity-type drift region,
wherein the end portion of said second-conductivity-type buried region on said second-conductivity-type base region side is located, in the thickness-wise direction of said first-conductivity-type drift region, at an almost same level with the level of the end portion of said gate electrode in said first-conductivity-type drift region.

2. The semiconductor device as claimed in claim 1, wherein said second-conductivity-type buried region comprises at least two regions disposed as being spaced from each other in the thickness-wise direction of said first-conductivity-type drift region, and
wherein the end portion on said second-conductivity-type base region side of one region, closest of these regions to said second-conductivity-type base region, is located at an almost same level with the level of the end portion of said gate electrode in said first-conductivity-type drift region, in the thickness-wise direction of said first-conductivity-type drift region.

3. The semiconductor device as claimed in claim 1, wherein said second-conductivity-type buried region is formed in a region of said first-conductivity-type drift region, which falls between a plurality of said gate electrodes in a plan view.

4. The semiconductor device as claimed in claim 2, wherein said second-conductivity-type buried region is formed in a region of said first-conductivity-type drift region, which falls between a plurality of said gate electrodes in a plan view.
